(19) United States
(12) Patent Application Publication
(10) Pub. No.: US 2025/0071949 A1
(43) Pub. Date: Feb. 27, 2025

(54) ELECTRICAL CONNECTOR AND ELECTRICAL CONNECTOR ASSEMBLY

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventors: MING-XIANG CHEN, New Taipei (TW); KUO-CHUN HSU, New Taipei (TW); WEN-NAN HSU, New Taipei (TW); YU-YUAN SHEN, New Taipei (TW); TSANG-HO YANG, New Taipei (TW)

(21) Appl. No.: 18/808,385

(22) Filed: Aug. 19, 2024

(30) Foreign Application Priority Data
Aug. 23, 2023 (CN) 202311068309.X

(51) Int. Cl. H05K 7/20; H01R 12/73; H01R 13/506

(52) U.S. Cl. CPC H05K 7/2049; H01R 12/732; H01R 13/506

(57) ABSTRACT

An electrical connector assembly includes an electrical connector having a card slot and plural terminals extending into the card slot; and a heat dissipation module having a fixing plate at one end thereof, the fixing plate having a notch; wherein the electrical connector has a supporting surface for supporting the fixing plate and a fixing member for mating with the notch, the fixing member includes a spherical or hemispherical head portion for guiding the fixing plate at multiple angles.

### BACKGROUND OF THE INVENTION

### Field of the Invention

The present invention relates generally to an electrical connector and an assembly of the same, and particularly to an electrical connector adapted for being plugged with a card module.

### Description of Related Arts

Taiwan Patent No. TWI772461B discloses an electrical connector and a heat dissipation module. The heat dissipation module is placed on the card edge connector and fixed by bolts. When the heat dissipation module is fixed by bolts, the operator needs to perform precise alignment which is generally assembled manually. The installing and disassembling operations of the heat dissipation module are cumbersome. In addition, when there are two or more bolts fixing the heat dissipation module, it is possible that different bolts exert different pressures on the heat dissipation module, thereby affecting the heat dissipation effect.

An improved electrical connector is desired.

### SUMMARY OF THE INVENTION

An object of the present invention is to provide an electrical connector and an assembly of the same that facilitate the plugging of a heat dissipation module.

To achieve the above-mentioned object, an electrical connector assembly includes an electrical connector having a card slot and a plurality of terminals extending into the card slot; and a heat dissipation module having a fixing plate at one end thereof, the fixing plate having a notch; wherein the electrical connector has a supporting surface for supporting the fixing plate and a fixing member for mating with the notch, and the fixing member comprises a spherical or hemispherical head portion for guiding the fixing plate at multiple angles.

Other advantages and novel features of the invention will become more apparent from the following detailed description of the present embodiment when taken in conjunction with the accompanying drawings.

### BRIEF DESCRIPTION OF THE DRAWING

FIG. 1 is a perspective view of an electrical connector assembly of a first embodiment of the present invention;

FIG. 2 is a side view of the electrical connector and the heat dissipation module before docking;

FIG. 3 is a cross-sectional view of a docking process of the electrical connector and the heat dissipation module of FIG. 1 taken along lines A-A;

FIG. 4 is a side view of the electrical connector docking with the heat dissipation module;

FIG. 5 is a perspective view of the electrical connector of FIG. 1;

FIG. 6 is an exploded perspective view of the electrical connector of FIG. 5;

FIG. 7 is another exploded perspective view of the electrical connector of FIG. 5;

FIG. 8 is a further exploded perspective view of the electrical connector of FIG. 7;

FIG. 9 is a perspective view of an electrical connector assembly of a second embodiment of the present invention;

FIG. 10 is an exploded perspective view of the electrical connector of FIG. 9;

FIG. 11 is a perspective view of an electrical connector assembly of a third embodiment of the present invention;

FIG. 12 is a perspective view of an electrical connector assembly of a fourth embodiment of the present invention;

FIG. 13 is an exploded perspective view of the electrical connector assembly of FIG. 12;

FIG. 14 is a perspective view of an electrical connector of a fifth embodiment of the present invention;

FIG. 15 is an exploded perspective view of the electrical connector of FIG. 14;

FIG. 16 is a perspective view of an electrical connector of a sixth embodiment of the present invention;

FIG. 17 is an exploded perspective view of the electrical connector of FIG. 16;

FIG. 18 is a perspective view of an electrical connector assembly of a seventh embodiment of the present invention; and

FIG. 19 is an exploded perspective view of the electrical connector of FIG. 18.

### DETAILED DESCRIPTION OF THE PREFERRED EMBODIMENT

Reference will now be made to the drawing figures to describe the preferred embodiment of the present invention in detail.

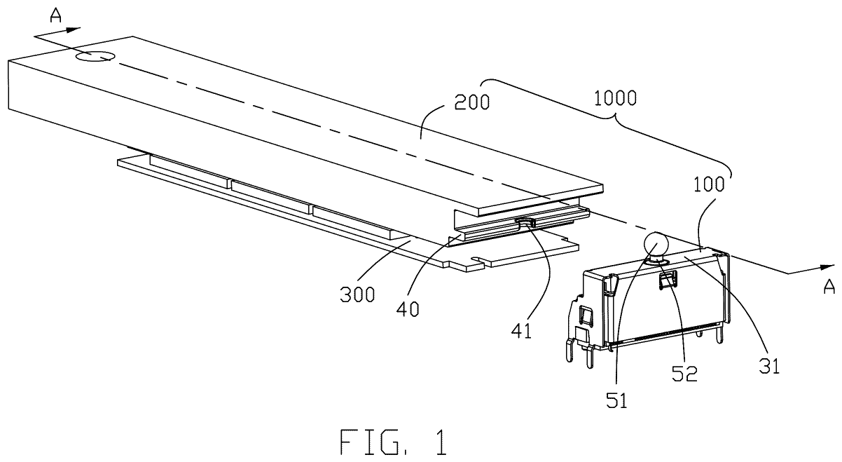

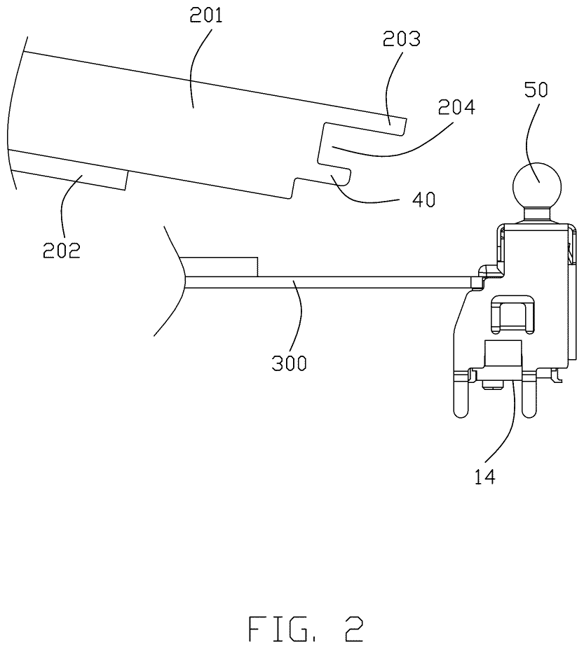

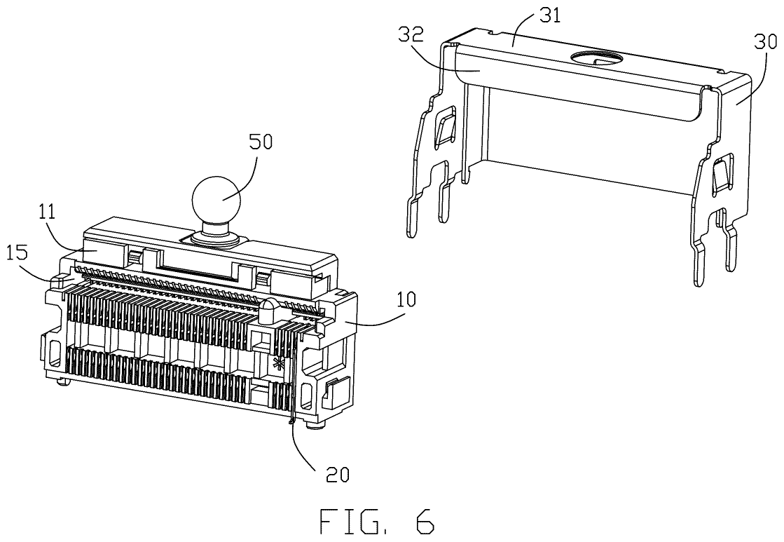

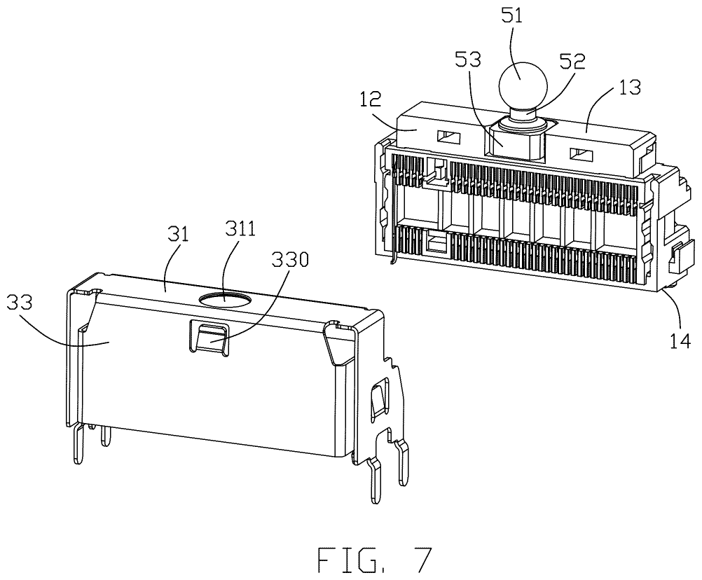

Referring to FIGS. 1-8, an electrical connector assembly 1000 of a first embodiment of this present invention includes an electrical connector 100 and a heat dissipation module 200. The electrical connector 100 includes an insulating housing 10, a plurality of terminals 20, and a metallic shell 30. As shown in FIGS. 6-7, the insulating housing 10 has a front face 11, a rear face 12 opposite to the front face 11, a top face 13 and a bottom face 14. The bottom face 14 is mounted on a circuit board (not shown). The top face 13 and the bottom face 14 are located between the front and rear faces. The electrical connector 100 has a card slot 15 penetrating the front face 11. The terminals 20 extend into the card slot 15 to connect with a card module 300 inserted into the card slot 15, only part of the terminals 20 are shown in the figures. Referring to FIG. 1, the heat dissipation module 200 has a fixing plate 40 at one end thereof, the fixing plate 40 has a notch 41. The electrical connector 100 has a supporting surface 310 for supporting the fixing plate 40 and a fixing member 50 for mating with the notch 41. The fixing member 50 comprises a spherical head portion 51 for guiding the fixing plate 41 at multiple angles. When assembling the heat dissipation module 200, the fixing member 50 can be used as an axis to achieve the matching of the notch 41 and the fixing member 50 at multiple angles and directions, which can make the assembly process of the heat dissipation module 200 simpler and easier.

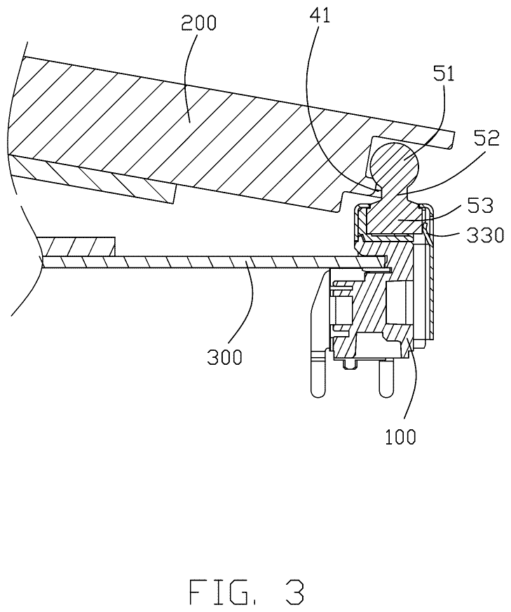

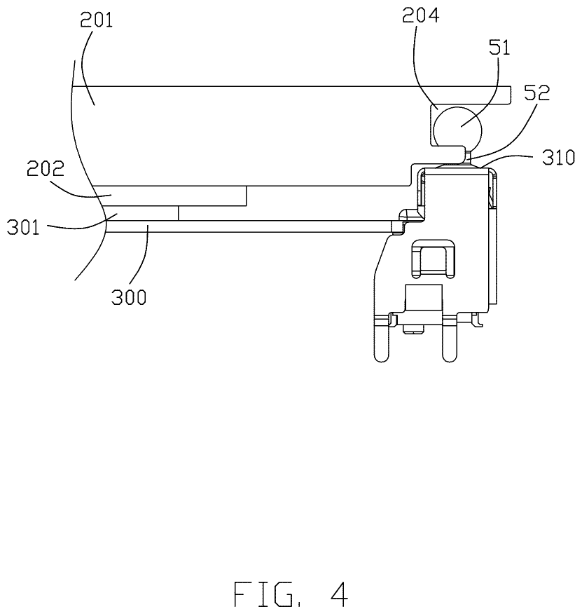

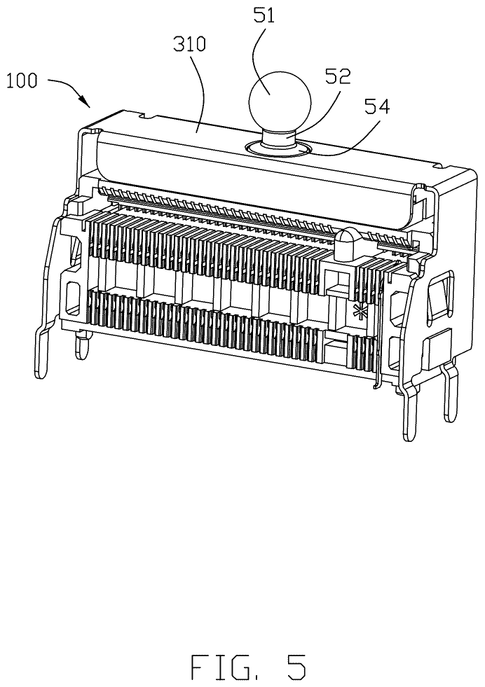

Referring to FIGS. 5-8, the metallic shell 30 includes a top plate 31 attached to the top face 13 of the insulating housing 1, a rear plate 33 attached to the rear face 12, and a front plate 32 attached to the front face 11. The supporting surface 310 is formed on the top plate 31 of the metallic shell 30. A lower end 53 of the fixing member 50 is fixed on the supporting surface 310 or fixed to the insulating housing 1 passing through the supporting surface 310. A neck 52 is formed between the supporting surface 310 and the head portion 51. A size of the neck 52 is smaller than that of the head portion 51. Referring to FIGS. 3-4, the neck 52 is accommodated in the notch 41. The head portion 51 is stuck on the other side of the fixing plate 40 opposite to the supporting surface 310. Referring to FIGS. 1-4, the heat dissipation module 200 includes a heat dissipation body 201, a heat dissipation head 202 disposed below the heat dissipation body 201. The heat dissipation head 202 abuts against the card module 300 or a solid state hard disk 301 disposed on the card module 300. The fixing plate 41 is disposed at one end of the heat dissipation body 201. An upper surface 203 of the heat dissipation body 201 extends above the fixing plate 41. A gap 204 for accommodating the head portion 51 is located between the fixing plate 41 and the upper surface 203.

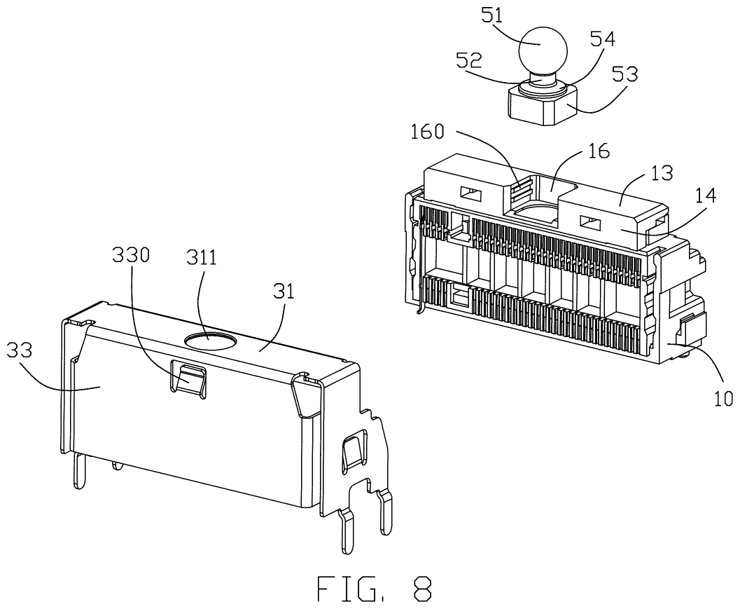

As shown in FIGS. 7-8, the insulating housing 10 has a receiving groove 16 penetrating through the top face 13 and the rear face 12. The lower end 53 of the fixing member 50 is arranged in the receiving groove 16. An inner wall of the receiving groove 16 comprises a plurality of convex ribs 160, the lower end 53 is interfered with the convex ribs 160. A guide portion 54 is formed between the lower end 53 of the fixing member 50 and the neck 52. The guide portion 54 tapers from the lower end 53 of the fixing member 50 to the neck 52. The top plate 31 has a through hole 311 for passing through the fixing member 50. As shown in FIG. 5, the guide portion 54 is exposed to the through hole 311. The guide portion 54 is a smooth inclined face or a round face, which can guide the fixing plate 40 of the heat dissipation module 200 to be plugged and unplugged smoothly. The rear plate 33 has an elastic sheet 330, referring to FIG. 3, the elastic sheet 330 abuts against the lower end 53 of the fixing member 50 from the back to the front for enhancing the stability of the assembly of the fixing member 50.

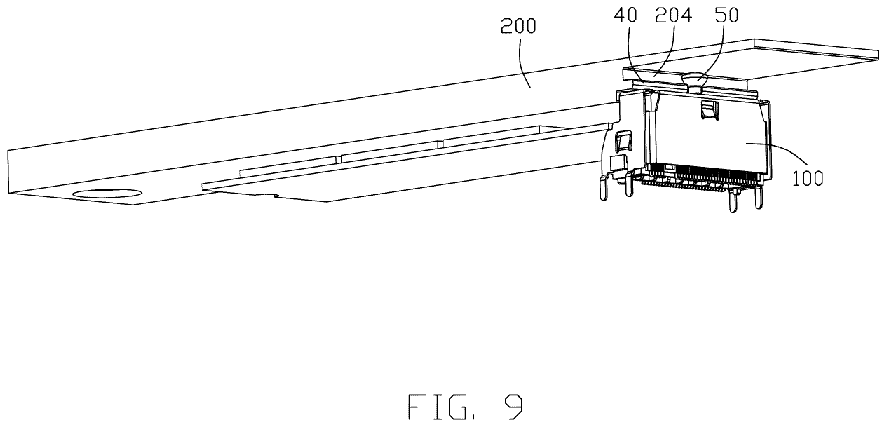

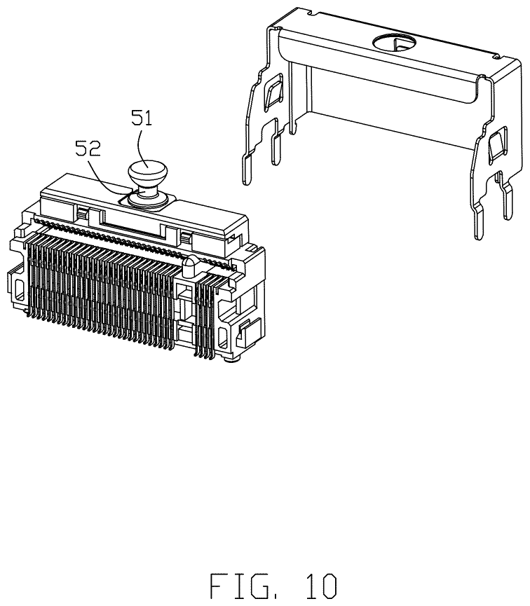

Referring to FIGS. 9-10, most of the structures of the second embodiment of the present invention are the same as those of the first embodiment, except that the head portion 51 of the fixing member 50 is hemispherical, except that the head portion 51 of the fixing member 50 has a hemispherical shape. The side where the head portion 51 and the neck 52 are connected is set to be hemispherical. When the heat dissipation module 200 is assembled, the notch 41 and the fixing portion 50 can cooperate with each other at multiple angles and directions, and the heat dissipation module 200 can be withdrawn directly when it rotates to a certain angle.

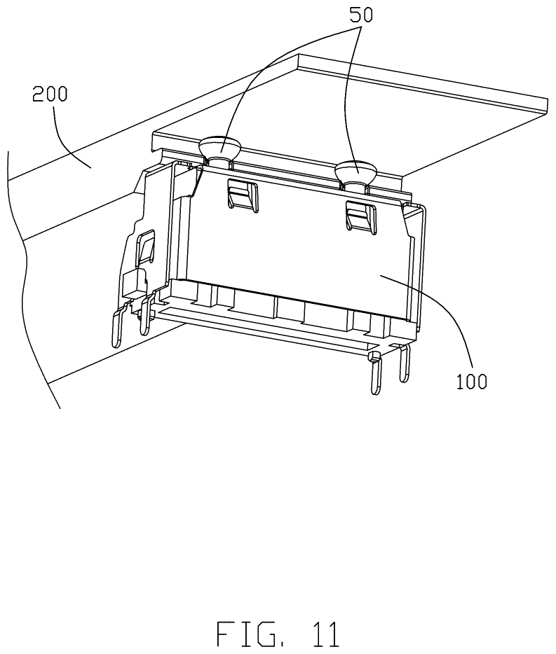

Referring to FIG. 11, compared to the second embodiment, the electrical connector 100 of the third embodiment has two fixing members 50, and the heat dissipation module 200 is has two notches 41 correspondingly. The two fixing members 50 are arranged symmetrically. There are two fixing points between the heat dissipation module 200 and the electrical connector 100, which can increase the stability of the assembly of the heat dissipation module 200 and the electrical connector 100.

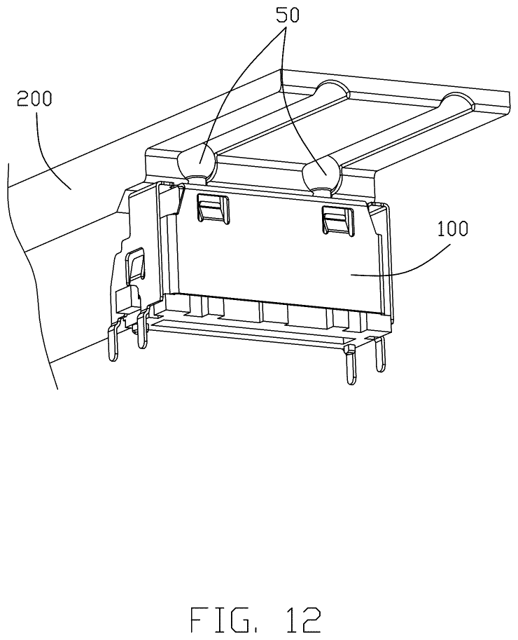

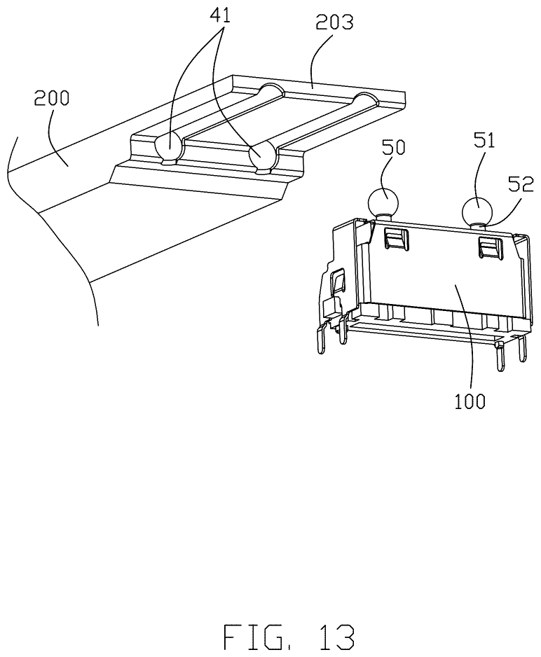

Referring to FIGS. 12-13, compared to the second embodiment, the electrical connector 100 of the fourth embodiment has two fixing members 50, and the heat dissipation module 200 is has two notches 41 correspondingly. The two fixing members 50 are arranged symmetrically. There are two fixing points between the heat dissipation module 200 and the electrical connector 100, which can increase the stability of the assembly of the heat dissipation module 200 and the electrical connector 100. In the fourth embodiment, the notch 41 is configured to fit the shape of the fixing member 50, the neck 52 and the head portion 51 are accommodated in the notch 41. Apart of the notch 41 extends to the upper surface 203 of the heat dissipation module 200, so that the fixing member 50 and the notch 41 can be matched to the greatest extent, which is beneficial to improving the stability of the assembly of the heat dissipation module 200. A part of the notch 41 extends to the upper surface 203 of the heat dissipation module 200, which can make the fixing member 50 and the notch 41 more matched in shape, and is conducive to improving the stability of the assembly of the heat dissipation module 200.

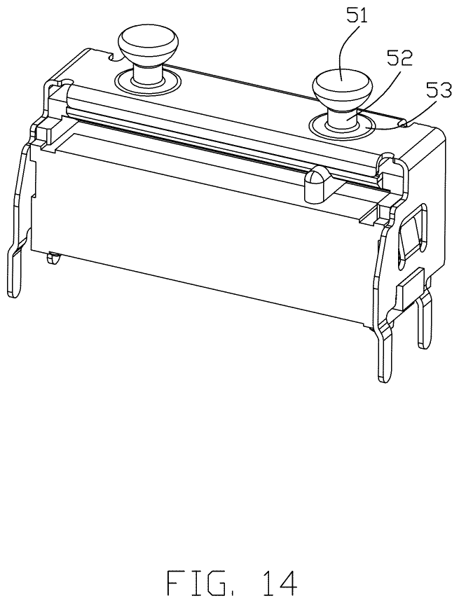

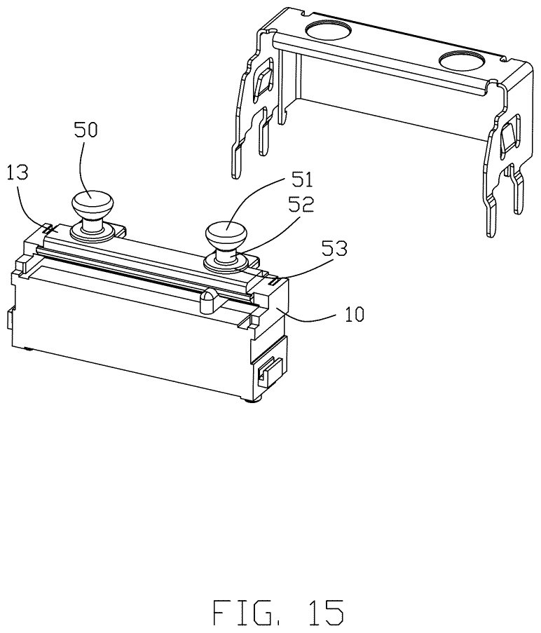

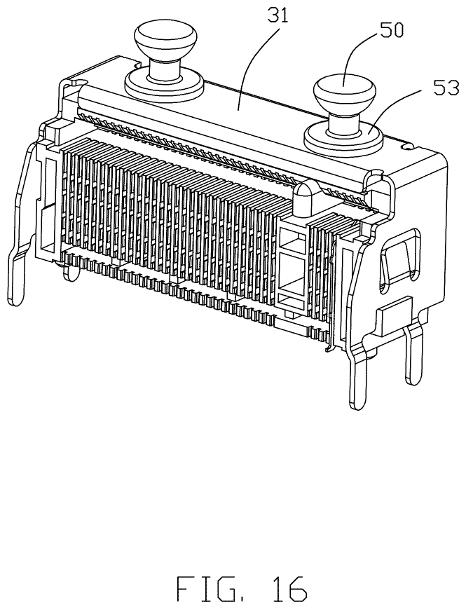

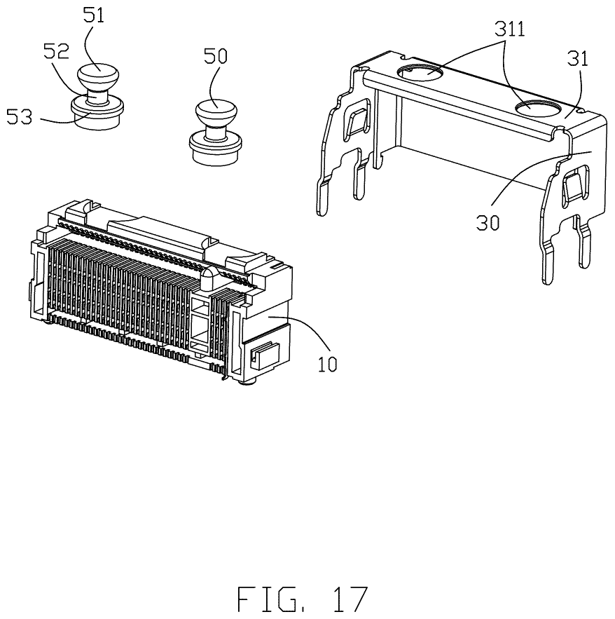

FIGS. 14-15 illustrate the fifth embodiment of the present invention, in which the heat dissipation module 200 is omitted. Most of the structures of the fifth embodiment is the same as the second embodiment, except that the lower end 53 of the fixing member 50 is formed with the insulating housing 10 integrally and extends from the top face 13 directly, which can make the assembly process more simply. FIGS. 16-17 illustrate the sixth embodiment of the present invention, in which the heat dissipation module 200 is omitted. Most of the structures of the fifth embodiment is the same as the second embodiment, except that the fixing member 50 is made of metal. The lower end 53 of the fixing member 50 is riveted joint the through hole 311 of the top plate 31 of the metallic shell 30, so that the fixing member 50 is fixed to the metallic shell 30.

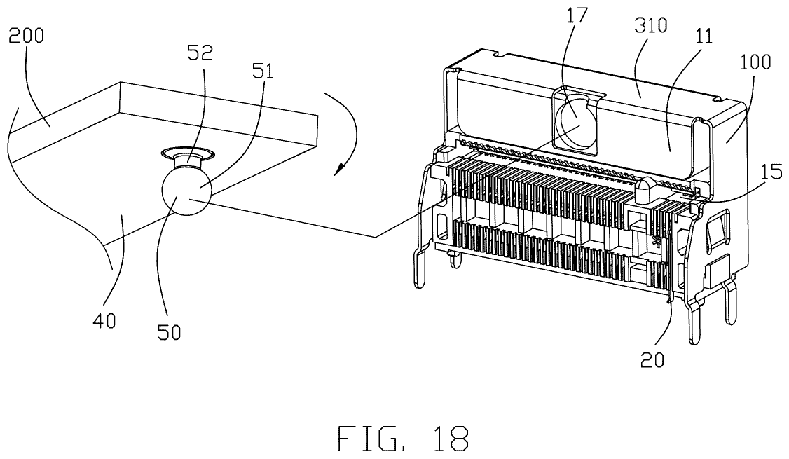

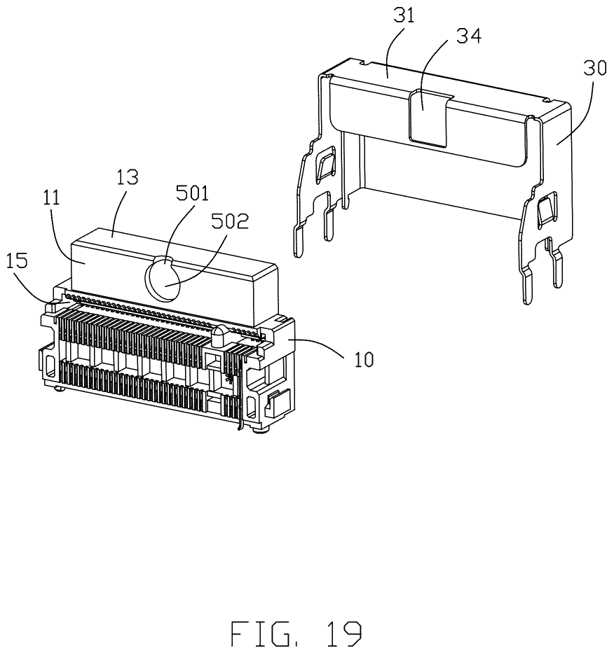

FIGS. 18-19 illustrate the seventh embodiment of the present invention, and most of its structure is the same as the first embodiment, except that in the seventh embodiment, the fixing member 50 is arranged on the heat dissipation module 200, and the notch 17 matched with the fixing member 50 is arranged on the electrical connector 100. Specifically, the electrical connector 100 has a card slot 15 penetrating the front face 11 and a plurality of terminals 20 extending into the card slot 15. The heat dissipation module 200 has a fixing plate 40 at one end thereof, the electrical connector 100 has a supporting surface 310 for supporting the fixing plate 40. The supporting surface 310 is located above the card slot 15. The top plate 31 of the metallic shell 30 is the supporting surface 310. The heat dissipation module 200 comprises a fixing member 50 extending downward from the fixing plate 40. The electrical connector 100 comprises a notch 17 penetrating the supporting surface 310. The fixing member 50 is received in the notch 17. The fixing member 50 has a spherical head portion 51. In other embodiments, the fixing member 50 may also has a hemispherical head portion 51. The notch 17 runs through the front face 11 and the top face 13 of the insulating housing 10. The fixing member 50 has a neck 52 located between the fixing plate 40 and the head portion 51. A size of the neck 52 is smaller than that of the head portion 51. The fixing member 50 is partially received in the notch 17. The notch 17 is arranged according to the shape of the fixing member 50 and comprises a bayonet 501 clamped on the neck 52 and a groove 502 accommodating the head portion 51. The metallic shell 30 comprises a top plate 31 attached to the top face 13 of the insulating housing 10, a front plate 32 attached to the front face 11, and an opening 34. The supporting surface 310 is formed on the top plate 31 of the metallic shell 30. The opening 34 penetrates through the top plate 31 and the front plate 32. The notch 17 exposes to the opening 34. In other embodiments, the supporting surface 310 or the top face 13 extends forward beyond the front face 11, the notch 17 penetrates through the supporting surface 310 or the top face 13 and is clamped on the neck 52 of the fixing member 50.

In summary, the second to seventh embodiments of the present invention are modifications made on the basis of the first embodiment. The convenience of dismantling the heat dissipation module 200 can be increased by setting the head portion 51 of the fixing member 50 to be hemispherical. The stability of assembling the heat dissipation module 200 and the electrical connector 100 can be increased by setting a plurality of fixing members 50 and notches 41. The assembly steps can be simplified by forming the fixing member 50 and the insulating housing 10 integrally. The assembly selectivity can be increased by riveting the fixing member 50 and the metallic shell 30. The positions of the fixing member and the notch can be selected adaptively to be interchanged according to needs.

The above-mentioned embodiments are only preferred embodiments of the present invention, and should not limit the scope of the present invention, any simple equivalent changes and modifications made according to the claims of the present invention and the contents of the description should still belong to the present invention.

1. An electrical connector assembly comprising:
an electrical connector having a card slot and a plurality of terminals extending into the card slot; and
a heat dissipation module having a fixing plate at one end thereof, the fixing plate having a notch;
wherein the electrical connector has a supporting surface for supporting the fixing plate and a fixing member for mating with the notch, and the fixing member comprises a spherical or hemispherical head portion for guiding the fixing plate at multiple angles.

2. The electrical connector assembly as claimed in claim 1, wherein the electrical connector comprises one or two fixing members, and the heat dissipation module comprises one or two corresponding notches.

3. The electrical connector assembly as claimed in claim 1, wherein a lower end of the fixing member is fixed on the supporting surface or fixed to other parts of the electrical connector passing through the supporting surface, a neck is formed between the supporting surface and the head portion, a size of the neck is smaller than that of the head portion, the neck is accommodated in the notch, and the head portion is stuck on an other side of the fixing plate opposite to the supporting surface.

4. The electrical connector assembly as claimed in claim 1, wherein a lower end of the fixing member is fixed on the supporting surface or fixed to other parts of the electrical connector passing through the supporting surface, a neck is formed between the supporting surface and the head portion, a size of the neck is smaller than that of the head portion, and the neck and the head portion are accommodated in the notch.

5. An electrical connector comprising:
a card slot;
a plurality of terminals extending into the card slot;
a supporting surface located above the card slot; and
a fixing member located above the card slot;
wherein a lower end of the fixing member is fixed at the supporting surface, an upper end of the fixing member has a head portion, a neck is formed between the upper end and the lower end of the fixing member, and the head portion has a spherical or hemispherical shape for multi-angle guidance.

6. The electrical connector as claimed in claim 5, wherein the electrical connector comprises one or two fixing members.

7. The electrical connector as claimed in claim 5, wherein the electrical connector comprises an insulating housing, the terminals, and a metallic shell, the insulating housing has a front face, a rear face opposite to the front face, a top face and a bottom face, the top face and the bottom face are located between the front and rear faces, the card slot penetrates the front face, and the lower end of the fixing member is fixed on the insulating housing or formed with the insulating housing integrally.

8. The electrical connector as claimed in claim 7, wherein the metallic shell comprises a top plate attached to the top face of the insulating housing and a rear plate attached to the rear face, the supporting surface is formed on the top plate of the metallic shell, and the fixing member extends through the metallic shell.

9. The electrical connector as claimed in claim 8, wherein the insulating housing has a receiving groove penetrating through the top face and the rear face, and the lower end of the fixing member is arranged in the receiving groove.

10. The electrical connector as claimed in claim 9, wherein an inner wall of the receiving groove comprises a convex rib, and the lower end is interference fit with the convex rib.

11. The electrical connector as claimed in claim 9, wherein the rear plate has an elastic sheet abutting against the lower end of the fixing member from the back to the front.

12. The electrical connector as claimed in claim 8, wherein a guide portion is formed between the lower end of the fixing member and the neck, the guide portion tapers from the lower end of the fixing member to the neck, the top plate has a through hole for passing through the fixing member, and the guide portion is exposed to the through hole.

13. The electrical connector as claimed in claim 5, wherein the electrical connector comprises an insulating housing, the terminals, and a metallic shell, the insulating housing has a front face, a rear face opposite to the front face, a top face and a bottom face, the top face and the bottom face are located between the front and rear faces, the card slot penetrates the front face, the metallic shell comprises a top plate covering the top face of the insulating housing, the supporting surface is formed on the top plate and has a through hole, and the lower end of the fixing member is riveted joint the through hole to fix the fixing member on the metallic shell.

14. An electrical connector assembly comprising:
an electrical connector having a card slot penetrating a front face thereof and a plurality of terminals extending into the card slot; and
a heat dissipation module having a fixing plate at one end thereof;
wherein the electrical connector has a supporting surface for supporting the fixing plate, the heat dissipation module comprises a fixing member extending downward from the fixing plate, the electrical connector comprises a notch penetrating the supporting surface, the fixing member is received in the notch, and the fixing member has a spherical or hemispherical head portion.

15. The electrical connector assembly as claimed in claim 14, wherein the notch runs through the front face, the fixing member has a neck located between the fixing plate and the head portion, a size of the neck is smaller than that of the head portion, and the fixing member is partially received in the notch.

16. The electrical connector assembly as claimed in claim 15, wherein the notch is arranged according to the shape of the fixing member and comprises a bayonet clamped on the neck and a groove accommodating the head portion.

17. The electrical connector assembly as claimed in claim 16, wherein the heat dissipation module comprises one or two fixing members, and the electrical connector comprises one or two corresponding notches.

18. The electrical connector assembly as claimed in claim 16, wherein the electrical connector comprises an insulating housing, the terminals, and a metallic shell, the insulating housing has a front face, a rear face opposite to the front face, a top face, and a bottom face, the top face and the bottom face are located between the front and rear faces, the card slot penetrates the front face, and the notch runs through the front face and the top face.

19. The electrical connector assembly as claimed in claim 18, wherein the metallic shell comprises a top plate attached to the top face of the insulating housing, a front plate attached to the front face, and an opening, the supporting surface is formed on the top plate of the metallic shell, the opening penetrates through the top plate and the front plate, and the notch is exposed to the opening.

20. The electrical connector assembly as claimed in claim 14, wherein the supporting surface extends forward beyond the front face, and the notch penetrates through the supporting surface and is clamped on the fixing member.
